(19) United States
(12) Patent Application Publication
(10) Pub. No.: US 2009/0200672 A1
(43) Pub. Date: Aug. 13, 2009

(54) METHOD FOR MANUFACTURING SEMICONDUCTOR DEVICE

(76) Inventors: Soo Hyun KIM, Seoul (KR); Kwan Yong LIM, Kyoungki-do (KR); Baek Mann KIM, Kyoungki-do (KR); Young Jin LEE, Kyoungki-do (KR); Noh Jung KWAK, Kyoungki-do (KR); Hyun Chul SOHN, Seoul (KR)

Correspondence Address: LADAS & PARRY LLP, 224 SOUTH MICHIGAN AVENUE, SUITE 1600, CHICAGO, IL, 60604, US

(21) Appl. No.: 12/427,894

(22) Filed: Apr. 22, 2009

Related U.S. Application Data
(62) Division of application No. 11/512,572, filed on Aug. 30, 2006.

(30) Foreign Application Priority Data
Dec. 28, 2005 (KR) 10-2005-0132135

(51) Int. Cl. H01L 23/52; H01L 21/336; H01L 21/4763

(52) U.S. Cl. 257/751; 438/592; 438/653; 257/E23.141; 257/E21.409; 257/E21.495

(57) ABSTRACT

Disclosed is a method for manufacturing a semiconductor device. This method includes the step of forming a diffusion barrier film, which is interposed between a silicon film and a metal film and functions to prevent diffusion between the silicon and metal films. The diffusion barrier film is formed of a WSixNy film or a WSix film by using an ALD process.

### FIELD OF THE INVENTION

The present invention relates to a method for manufacturing a semiconductor device, and more particularly to a method for manufacturing a semiconductor device to reduce or prevent RC delay phenomenon caused by a diffusion barrier film interposed between a silicon film and a metal film reacting with the silicon film to form a dielectric film such as a SiNx film.

### BACKGROUND OF THE INVENTION

In manufacturing a semiconductor device such as a dynamic random access memory device or “DRAM,” doped polysilicon (poly-Si), tungsten (W), aluminum (Al) or the like, is often the material used to form wirings, including gate and a bit line wirings, and as the material of a wiring contact plug. Also, research is being pursued to use low-resistance material such as copper (Cu), which is easy to apply to a highly integrated device and which can improve operation characteristics of the device because of resistance that is lower than the above-mentioned materials, as next-generation wiring material.

Hereinafter, a detailed description will be given of electrically conductive materials, which are used for the gate functioning as a switch of a MOSFET device, from among the wiring and the wiring contact plug as stated above.

As is well known in the art, the gate of a MOSFET is usually formed of polysilicon. This is because polysilicon sufficiently satisfies physical properties required for the gate, for example, high melting point thereof, easiness to form a thin film, easiness of line patterning, stability against an oxidizing atmosphere, and flat surface formability. Also, in an MOSFET device, the gate formed of polysilicon realizes low resistance by containing dopants such as phosphorous (P), arsenic (As) and boron (B).

However, since parameter values, such as line width of the gate, thickness of a gate insulating film, junction depth and so forth, have decreased with an increase in the density of a semiconductor device, polysilicon shows a limitation on the realization of low resistance required for fine line width. Diversified research is being pursued on materials for a gate electrode and, as an example, a gate electrode having a laminated structure of polysilicon and tungsten has been proposed.

A gate electrode having a laminated structure of polysilicon and tungsten makes it possible to realize low resistance according to the fine line width because tungsten has low resistivity and good thermal stability. Afterwards, it is expected to make much use of such a gate electrode in manufacturing a highly integrated device.

FIGS. 1A and 1B illustrate process-by-process sectional views for explaining a method for forming a gate electrode having a laminated structure of polysilicon and tungsten according to the prior art.

Referring to FIG. 1A, a gate oxide film 3, a polysilicon film 4, a tungsten nitride film (WNx film) 5, a tungsten film 6 and a hard mask film 7 are formed on a semiconductor substrate 1 provided with a device isolation film 2 for defining an active area. The tungsten nitride film 5 functions as a diffusion barrier film for preventing dopants and silicon from diffusing from the polysilicon film 4 into the tungsten film 6. Next, these films 7, 6, 5, 4, 3 are etched to form the gate 8 structure as shown in FIG. 1A.

Referring to FIG. 1B, the substrate, on which the gate 8 described above has been formed, is subjected to heat treatment under an oxidizing atmosphere in order not only to repair damage arising from the etching process for forming the gate 8, that is, etching damage having occurred on sidewalls of the gate oxide film 3 and the ploy-silicon film 4, and a surface of the semiconductor substrate 1, but also to prevent damage from being caused by Lightly Doped Drain (hereinafter referred to as “LDD”) ion implantation to be performed in a subsequent process.

At this time, the heat treatment process is performed as a selective oxidation process in which only silicon is oxidized so as to prevent the tungsten film 6 from being oxidized, as a result of which an oxide film 9 is formed on the surface of the semiconductor substrate 1, and the sidewalls of the gate oxide film 3 and the polysilicon film 4. Thereafter, well-known processes are successively performed to finally manufacture a semiconductor device.

In the above-mentioned conventional method for manufacturing a semiconductor device, the tungsten nitride film 5, which is used as a diffusion barrier film during the selective oxidation process, reacts with the polysilicon film 4 to form a SiNx film and a WSix film, which results from the fact that W—N bonds in the tungsten nitride film 5 is easily broken due to a weak W—N bonding force during high-temperature heat treatment.

Referring to FIG. 2, which illustrates a ternary phase diagram of W—Si—N, it can be seen that there is no tie line between WNx and Si. This means that a junction between WNx and Si is not thermodynamically stable, and a third substance such as SiNx is produced at a junction interface thereof.

The SiNx film, which is formed between the polysilicon film 4 and the tungsten nitride film 3 in this way, acts like a dielectric film of a capacitor during high-frequency operation to increase the resistance of the gate electrode and thus cause a RC delay phenomenon of a word line. Consequently, the operation speed of the device is lowered.

Therefore, there is a need for a diffusion barrier film formed of new material capable of effectively blocking diffusion between a silicon film and a metal film without causing the above-mentioned problem.

### SUMMARY OF THE INVENTION

Accordingly, an object of the present invention is to provide a semiconductor device manufacturing method capable of reducing or even preventing a RC delay phenomenon caused when a diffusion barrier film interposed between a silicon film and a metal film reacts with the silicon film to form a dielectric film such as a SiNx film.

In order to accomplish this object, in accordance with one aspect of the present invention, there is provided a method for manufacturing a semiconductor device comprising the step of forming a diffusion barrier film, which is interposed between a silicon film and a metal film and functions to prevent diffusion between the silicon and metal films, the diffusion barrier film being formed of a WSixNy film by using an Atomic Layer Deposition (ALD) process.

The metal film used in the method is any one or more metal films selected from of the group consisting of a tungsten film, a copper film and an aluminum film.

The WSixNy film is formed at a pressure of 10 mTorr to 10 Torr and a temperature of 300 to 500° C. by using the ALD process.

Also, in the step of forming the WSixNy film by using the ALD process, any one or more selected from the group consisting of WF6, WCl6, WBr6, W(CO)6, W(C2H2)6, W(PF3)6, W(allyl)4, (C2H5)WH2, [CH3(C5H4)]2WH2, (C5H5)W(CO)3(CH3), W(butadiene)3, W(methylvinyl-ketone)3, (C5H5) HW(CO) 3, (C7H8)W(CO)3 and (1,5-COD)W(CO)4 may be used as a W source gas.

Further, in the step of forming the WSixNy film by using the ALD process, any one or more selected from the group consisting of B2H6, BH3 and B10H14 may be used as a reducing gas for reducing the W source gas.

Further, in the step of forming the WSixNy film by using the ALD process, any one or more selected from the group consisting of SiH4, Si2H6 and SiH2Cl2 may be used as a Si source gas.

Further, in the step of forming the WSixNy film by using the ALD process, any one or more selected from the group consisting of NH3 and N2H4 may be used as a N source gas.

The WSixNy film may be formed by repeatedly performing a deposition cycle, in which W source gas supply and purge, reducing gas supply and purge, Si source gas supply and purge, and N source gas supply and purge are carried out in sequence, according to the ALD process.

The WSixNy film may also be formed by repeatedly performing a deposition cycle, in which reducing gas supply and purge, W source gas supply and purge, Si source gas supply and purge, and N source gas supply and purge are carried out in sequence, according to the ALD process.

The WSixNy film may also be formed by repeatedly performing a deposition cycle, in which reducing gas supply and purge, W source gas supply and purge, N source gas supply and purge, and Si source gas supply and purge are carried out in sequence, according to the ALD process.

The WSixNy film may also be formed by repeatedly performing a deposition cycle, in which W source gas supply and purge, reducing gas supply and purge, N source gas supply and purge, and Si source gas supply and purge are carried out in sequence, according to the ALD process.

Any one or more of, the reducing gas, the Si source gas and the N source gas may be supplied in a plasma state.

In accordance with another aspect of the present invention, there is provided a method for manufacturing a semiconductor device, the method comprising the step of forming a diffusion barrier film, which is interposed between a silicon film and a metal film and functions to prevent diffusion between the silicon and metal films, the diffusion barrier film being formed of a WSix film by using an ALD process.

The metal film is any one selected from of the group consisting of a tungsten film, a copper film and an aluminum film.

The WSix film is formed at a pressure of 10 mTorr to 10 Torr and a temperature of 300 to 500° C. by using the ALD process.

Also, in the step of forming the WSix film by using the ALD process, any one selected from the group consisting of WE6, WCl6, WBr6, W(CO)6, W(C2H2)6, W(PF3)6, W(allyl)4, (C2H5)WH2, [CH3(C5H4)]2WH2, (C5H5)W(CO)3(CH3), W(butadiene)3, W(methylvinyl-ketone)3, (C5H5)HW(CO)3, (C7H8)W(CO)3 and (1,5-COD)W(CO)4 may be used as a W source gas.

Further, in the step of forming the WSix film by using the ALD process, any one selected from the group consisting of B2H6, BH3 and B10H14 may be used as a reducing gas for reducing the W source gas.

Further, in the step of forming the WSix film by using the ALD process, any one selected from the group consisting of SiH4, Si2H6 and SiH2Cl2 may be used as a Si source gas.

The WSix film may be formed by repeatedly performing a deposition cycle, in which W source gas supply and purge, reducing gas supply and purge, and Si source gas supply and purge are carried out in sequence, according to the ALD process.

The WSix film may also be formed by repeatedly performing a deposition cycle, in which reducing gas supply and purge, W source gas supply and purge, and Si source gas supply and purge are carried out in sequence, according to the ALD process.

Any one or more of the reducing gas and the Si source gas may be supplied in a plasma state.

In accordance with another aspect of the present invention, there is provided a method for manufacturing a semiconductor device, the method comprising the steps of: forming a gate insulating film on a semiconductor substrate; forming a polysilicon film on the gate insulating film; forming a WSixNy film as a diffusion barrier film on the polysilicon film by using an ALD process; forming a metal film on the WSixNy film; and etching the metal film, the WSixNy film, the polysilicon film and the gate insulating film to form a gate.

In accordance with another aspect of the present invention, there is provided a method for manufacturing a semiconductor device, the method comprising the steps of: forming a gate insulating film on a semiconductor substrate; forming a polysilicon film on the gate insulating film; forming a WSix film as a diffusion barrier film on the polysilicon film by using an ALD process; forming a metal film on the WSix film; and etching the metal film, the WSix film, the polysilicon film and the gate insulating film to form a gate.

### BRIEF DESCRIPTION OF THE DRAWINGS

The above and other objects, features and advantages of the present invention will be more apparent from the following detailed description taken in conjunction with the accompanying drawings, in which:

FIGS. 1A and 1B are process-by-process sectional views for explaining a semiconductor device manufacturing method according to the prior art;

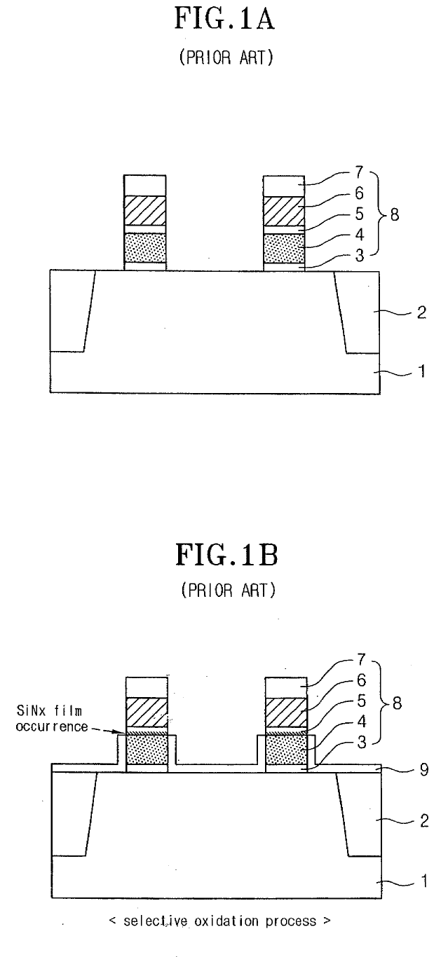

FIG. 2 is a ternary phase diagram of W—Si—N; and

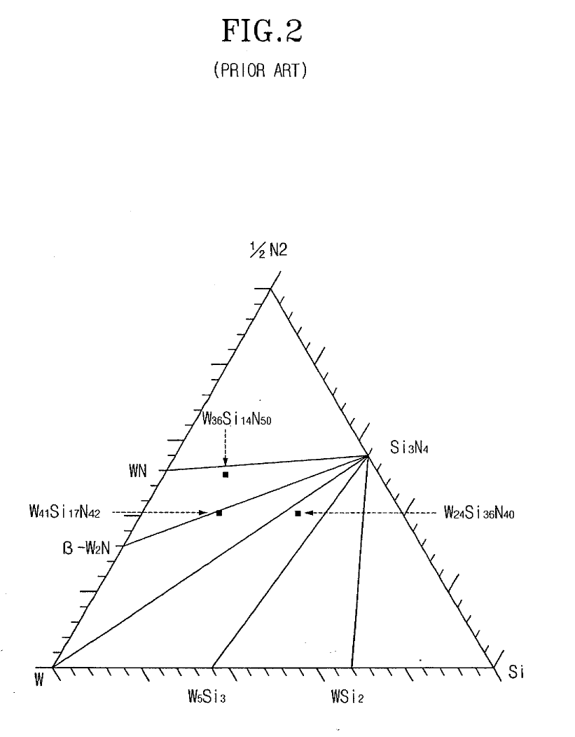

FIGS. 3A and 3B are process-by-process sectional views for explaining a semiconductor device manufacturing method in accordance with a preferred embodiment of the present invention.

### DETAILED DESCRIPTION OF THE PREFERRED EMBODIMENTS

Hereinafter, preferred embodiments of the present invention will be described with reference to the accompanying drawings. In the following description and drawings, the same reference numerals are used to designate the same or similar components, and so repetition of the description on the same or similar components will be omitted.

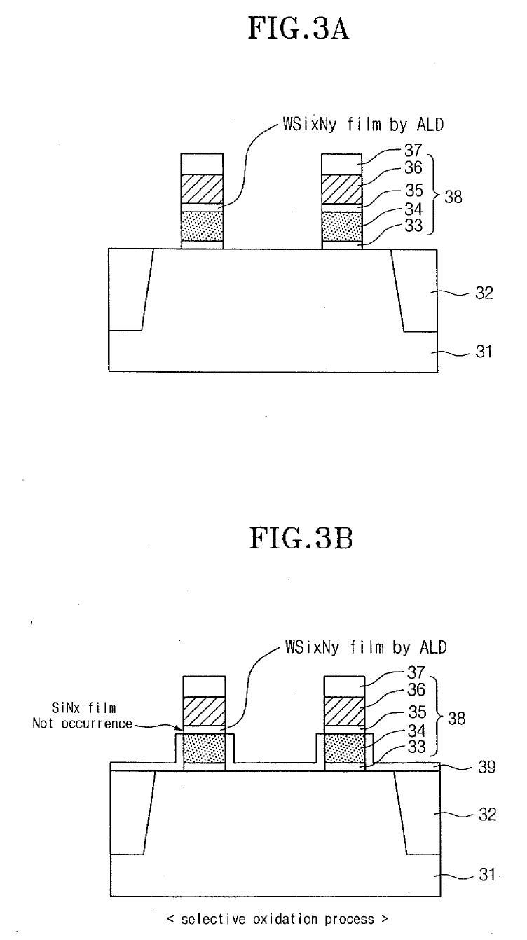

FIGS. 3A and 3B illustrate process-by-process sectional views for explaining a semiconductor device manufacturing method according to a preferred embodiment of the present invention.

Referring to FIG. 3A, a gate oxide film 33 and a polysilicon film 34 are formed in sequence on a semiconductor substrate 31 that is provided with a device isolation film 32 for defining an active area.

Next, a WSixNy film 35 is formed on the polysilicon film 34 as a diffusion barrier film by using an Atomic Layer Deposition (hereinafter referred to as “ALD”) process. Here, the WSixNy film 35 is formed at a pressure of 10 mTorr to 10 Torr and a temperature of 300 to 500° C. by using the ALD process. At this time, any one or more gases selected from the group consisting of WF6, WCl6, WBr6, W(CO)6, W(C2H2)6, W(PF3)6, W(allyl)4, (C2H5)WH2, [CH3(C5H4)]2WH2, (C5H5)W(CO)3(CH3), W(butadiene)3, W(methylvinyl-ketone)3, (C5H5)HW(CO)3, (C7H8)W(CO)3 and (1,5-COD)W(CO)4 may be used as a W source gas. Any one or more selected from the group consisting of B2H6, BH3 and B10H14 may be used as a reducing gas for reducing the W source gas, any one selected from the group consisting of SiH4, Si2H6 and SiH2Cl2 may be used as a Si source gas, and any one selected from the group consisting of NH3 and N2H4 may be used as a N source gas.

The ALD process for forming the WSixNy film progresses in such a manner that a first deposition cycle, a second deposition cycle, a third deposition cycle or a fourth deposition cycle, are performed repeatedly according to the ALD process.

In the first deposition cycle, W source gas supply and purge, reducing gas supply and purge, Si source gas supply and purge, and N source gas supply and purge are carried out in sequence. In the second deposition cycle, a reducing gas supply and purge, W source gas supply and purge, Si source gas supply and purge, and N source gas supply and purge are carried out in sequence. In the third deposition cycle, reducing a gas supply and purge, W source gas supply and purge, N source gas supply and purge, and Si source gas supply and purge are carried out in sequence. In the fourth deposition cycle, W source gas supply and purge, reducing gas supply and purge, N source gas supply and purge, and Si source gas supply and purge are carried out in sequence.

In addition, the reducing gas, the Si source gas and the N source gas may be supplied in a plasma state, which brings an advantage in that it is easy to deposit the WSixNy film because the reactivity of the gases is enhanced.

Next, a tungsten film 36 and a hard mask film 37 are formed on the WSixNy film 35. The films 37, 36, 35, 34, 33 are then etched to form a gate 38 as shown in FIG. 3A.

Referring now to FIG. 3B, the resultant substrate, on which the gate 38 has been formed, is subjected to a selective oxidation process, in which the resultant substrate is thermally treated under an oxidizing atmosphere, in order to not only repair damage arising from the etching process for forming the gate 38, that is, etching damage having occurred on sidewalls of the gate oxide film 33 and the ploy-silicon film 34, and a surface of the semiconductor substrate 31, but also to prevent damage from being caused by LDD ion implantation to be performed in a subsequent process. As a result of the selective oxidation process, an oxide film 39 is formed on the surface of the semiconductor substrate 31, and on the sidewalls of the gate oxide film 33 and the polysilicon film 34. Thereafter, well-known but not shown prior art processes are successively performed to finally manufacture a semiconductor device.

In this way, the present invention uses the WSixNy film 35 according to the ALD process as the diffusion barrier film between the silicon film and the metal film. This WSixNy film 35 does not form a dielectric film such as a SiNx film through the reaction with the silicon film during the thermal process because it has a strong Si—N bonding force as compared with the conventional diffusion barrier film, that is, the tungsten nitride film (WNx film), and thus has low reactivity with the silicon film.

Also, since the WSixNy film 35 as the diffusion barrier layer of the present invention is a film amorphousized by adding a third element of Si to a transient metal nitride film, it has an excellent diffusion barrier characteristic. Moreover, the WSixNy film 35 is a conductor having a resistivity of about 300 to 1000 μΩ, which correspond to an electrical conductivity characteristic sufficient to be applied to the gate electrode.

In addition to this, since the WSixNy film 35 of the present invention is formed using the ALD process, it has advantages in that its step coverage and film uniformity are superior, its formation temperature is relatively low, and its composition is easily controlled.

Although the above-mentioned embodiment of the present invention employs the WSixNy film as the diffusion barrier film between the silicon film and the metal film, the present invention is not limited to this, but may employ a WSix film according to the ALD process, instead of the WSixNy film, as the diffusion barrier film.

In a case of using the WSix film according to the ALD process as the diffusion barrier film between the silicon film and the metal film, the WSix film is also formed at a pressure of 10 mTorr to 10 Torr and a temperature of 300 to 500 by using the ALD process, as in the WSixNy film.

At this time, any one or more selected from the group consisting of WF6, WCl6, WBr6, W(CO)6, W(C2H2)6, W(PF3)6, W(allyl)4, (C2H5)WH2, [CH3(C5H4)]2WH2, (C5H5)W(CO)3(CH3), W (butadiene)3, W(methylvinyl-ketone)3, (C5H5) HW (CO) 3, (C7H8)W(CO)3 and (1,5-COD)W(CO)4 may be used as a W source gas. Any one or more selected from the group consisting of B2H6, BH3 and B10H14 may be used as a reducing gas for reducing the W source gas, and any one or more selected from the group consisting of SiH4, Si2H6 and SiH2Cl2 may be used as a Si source gas.

Also, the WSix film according to the ALD process is formed by repeatedly performing a first deposition cycle in which W source gas supply and purge, reducing gas supply and purge, and Si source gas supply and purge are carried out in sequence, or a second deposition cycle in which reducing gas supply and purge, W source gas supply and purge, and Si source gas supply and purge are carried out in sequence.

In forming the WSix film by using the ALD process, the reducing gas and the Si source gas may be supplied in a plasma state.

Similarly to the case of WSixNy film, when the WSix film according to the ALD process is used as the diffusion barrier film, the formation of the SiNx film can be suppressed. By suppressing the formation of the SiNx film, the RC delay phenomenon caused by the SiNx film can also be reduced or even prevented.

Although a process of forming a gate has been described in the above embodiments, the semiconductor manufacturing method of the present invention can be applied to both a process of forming a bit line and a process of forming a metal wiring contact plug, in addition to the process of forming a gate. Also, although the semiconductor manufacturing method of the present invention has been described based on a case where the metal film is a tungsten film, it can also be applied in a case where the metal film is an aluminum film or a copper film.

According to a semiconductor manufacturing method of the present invention as describe above, instead of a conventional WNx film formed using sputtering, a WSixNy film or a WSix film formed using an ALD process is applied as a diffusion barrier film between a silicon film and a metal film, as a result of which the formation of a dielectric film such as a SiNx film at an interface between the diffusion barrier film and the silicon film is suppressed during a thermal process, and thus it is possible to prevent an RC delay phenomenon in wirings from being caused by the SiNx film and to improve the operation speed of a device. Thus, the present method can be advantageously applied in manufacturing a high-speed device.

Also, since the WSixNy film as the diffusion barrier layer of the present invention is a film amorphousized by adding a third element of Si to a transient metal nitride film, it has an excellent diffusion barrier characteristic, which results in an superior diffusion barrier characteristic of the present invention to that of the prior art.

In addition to this, because the WSixNy film or the WSix film as the diffusion barrier film of the present invention is formed using the ALD process, a film formation process can be performed at relatively low temperature, and step coverage and uniformity of the formed diffusion barrier film can be improved.

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A method for manufacturing a semiconductor device, the method comprising the step of:
forming a diffusion barrier film, which is interposed between a silicon film and a metal film and functions to prevent diffusion between the silicon and metal films, the diffusion barrier film being formed of a WSix film by using an ALD process.

2. The method as claimed in claim 1, wherein the metal film is any one selected from of the group consisting of a tungsten film, a copper film and an aluminum film.

3. The method as claimed in claim 1, wherein the WSix film is formed at a pressure of 10 mTorr to 10 Torr and a temperature of 300 to 500° C. by using the ALD process.

4. The method as claimed in claim 1, wherein in the step of forming the WSix film by using the ALD process, any one selected from the group consisting of WF6, WCl6, WBr6, W(CO)6, W(C2H2)6, W(PF3)6, W(allyl)4, (C2H5)WH2, [CH3(C5H4)]2WH2, (C5H5)W(CO)3(CH3), W(butadiene)3, W(methylvinyl-ketone)3, (C5H5)HW(CO)3, (C7H8)W(CO)3 and (1,5-COD)W(CO)4 is used as a W source gas.

5. The method as claimed in claim 1, wherein in the step of forming the WSix film by using the ALD process, any one selected from the group consisting of B2H6, BH3 and B10H14 is used as a reducing gas for reducing the W source gas.

6. The method as claimed in claim 1, wherein in the step of forming the WSix film by using the ALD process, any one selected from the group consisting of SiH4, Si2H6 and SiH2Cl2 is used as a Si source gas.

7. The method as claimed in claim 1, wherein the WSix film is formed by repeatedly performing a deposition cycle, in which W source gas supply and purge, reducing gas supply and purge, and Si source gas supply and purge are carried out in sequence, according to the ALD process.

8. The method as claimed in claim 7, wherein any one or more of the reducing gas and the Si source gas is supplied in a plasma state.

9. The method as claimed in claim 1, wherein the WSix film is formed by repeatedly performing a deposition cycle, in which reducing gas supply and purge, W source gas supply and purge, and Si source gas supply and purge are carried out in sequence, according to the ALD process.

10. The method as claimed in claim 9, wherein any one or more of the reducing gas and the Si source gas is supplied in a plasma state.

11. A method for manufacturing a semiconductor device, the method comprising the steps of:
forming a gate insulating film on a semiconductor substrate;
forming a polysilicon film on the gate insulating film;
forming a WSix film as a diffusion barrier film on the polysilicon film by using an ALD process;
forming a metal film on the WSix film; and
etching the metal film, the WSix film, the polysilicon film and the gate insulating film to form a gate.

12. A semiconductor device comprising:
a diffusion barrier film, interposed between a silicon film and a metal film, said diffusion barrier film preventing diffusion between the silicon and metal films and being formed of a WSix film using an Atomic Layer Deposition (ALD) process.
